(19) United States
(12) Patent Application Publication
(10) Pub. No.: US 2011/0180924 A1
(43) Pub. Date: Jul. 28, 2011

(54) MEMS MODULE PACKAGE

(75) Inventors: Jyong-Yue TIAN, Taichung County (TW); Jen-Chuan Yeh, Changhua County (TW)

(73) Assignee: LINGSEN PRECISION INDUSTRIES, LTD., Taichung (TW)

(21) Appl. No.: 12/707,940

(22) Filed: Feb. 18, 2010

(30) Foreign Application Priority Data
Jan. 22, 2010 (TW) 99101854

(51) Int. Cl. H01L 23/04

(52) U.S. Cl. 257/704; 257/E23.181

(57) ABSTRACT

A MEMS module package includes a carrier, a lid capped on the carrier, a spacer disposed between the carrier and the lid, and a chip mounted on the spacer and electrically connected with the carrier. The spacer has a channel in communication between a chamber and a receiving hole of the lid, and the chip is received in the chamber of the lid and corresponding to the channel of the spacer. Therefore, an external signal can be transmitted from the receiving hole of the lid into the chamber of the lid through the channel of the spacer so as be received by the chip.

### BACKGROUND OF THE INVENTION

1. Field of the Invention

The present invention relates generally to a Micro-Electro-Mechanical System (hereinafter referred to as “MEMS”) module package, and more specifically to a MEMS module package that has a simple manufacturing process and high production yield.

2. Description of the Related Art

In order to improve the performance of a MEMS module package, the mechanical support strength and other environmental factors, such as interference of noises, must be taken into account during packaging of the MEMS module package. Some MEMS module packages have a particular structure. For example, a MEMS microphone includes a chip to receive an external signal from the bottom side thereof. In this case, a substrate of MEMS microphone needs to provide a curved channel corresponding to the bottom side of the chip for allowing the chip to receive the external signal.

According to conventional technologies, the substrate is made by stacking multiple plates together for the purpose of forming the curved channel, but the stacked substrate may encounter problems in raising the manufacturing cost and increasing the total height of the substrate. Besides, there is another conventional design to use a leadframe as the substrate. The leadframe has a lot of vacancies that needs to be filled with insulating glue so as to cause a complicated manufacturing process, and the leadframe may easily get deformed during reflow soldering to result in low production yield.

Therefore, it is desirable to provide a MEMS module package that eliminates the aforesaid drawbacks.

### SUMMARY OF THE INVENTION

It is one objective of the present invention to provide a MEMS module package that has the advantages of reducing the whole height, and lowering manufacturing cost, and simplifying the manufacturing process, and raising production yield.

To achieve this objective of the present invention, the MEMS module package comprises a carrier embodied as a ceramic substrate or a double-layer substrate, a lid capped on the carrier and having a chamber and a receiving hole in communication with the outsides, a spacer disposed between the carrier and the lid and provided with a channel in communication between the chamber and the receiving hole of the lid, and a chip received in the chamber of the lid, and electrically connected with the carrier, and mounted on the spacer in such a manner that the chip is corresponding to the curved channel.

By means of the aforesaid design, the MEMS module package can attain the purpose of reducing the whole height to lower manufacturing cost, and simplifying the manufacturing process to raise production yield.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a sectional view of a MEMS module package according to a first embodiment of the present invention, and

FIG. 2 is a sectional view of the MEMS module package according to a second embodiment of the present invention.

### DETAILED DESCRIPTION OF THE INVENTION

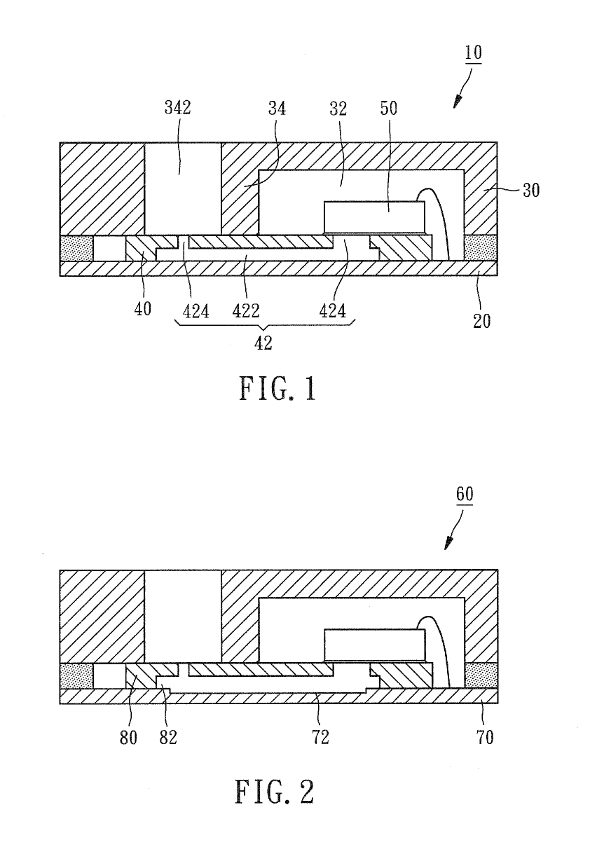

Referring to FIG. 1, a MEMS module package 10 in accordance with a first embodiment of the present invention comprises a carrier 20, a lid 30, a spacer 40, and a chip 50.

The carrier 20 can be a ceramic substrate or double-layer substrate, and is embodied as the ceramic substrate.

The lid 30 is capped on a surface of the carrier 20 and provided with a chamber 32 and a post 34 extending from a top wall of the chamber 32 and having a receiving hole 342 in communication with the outsides.

The spacer 40 is disposed between the carrier 20 and the lid 30, and has a curved channel 42 therein with a horizontal section 422 and two vertical sections 424. The vertical sections 424 each extend from one of two ends of the horizontal section 422 to respectively communicate with the chamber 32 and the receiving hole 342 of the lid 30.

The chip 50 is received in the chamber 32 of the lid 30, and electrically connected with the carrier 20, and mounted on the spacer 40 in such a manner that the chip 50 is corresponding to one of the vertical sections 424 of the curved channel 42. Therefore, an external signal can be transmitted from the receiving hole 342 of the lid 30 into the chamber 32 of the lid 30 through the curved channel 42 of the spacer 40 so as to be received by the chip 50.

When compared with the prior art, the MEMS module package 10 of the invention uses a single-layer or double-layer substrate as the carrier 20 to provide a stable structure and employs a thin spacer 40 to form the curved channel 42 such that MEMS module package 10 of the invention can attain the purpose of reducing the whole height of the MEMS module package 10, and lowering the manufacturing cost, and simplifying the manufacturing process, and raising production yield.

FIG. 2 illustrates a MEMS module package 60 in accordance with a second embodiment of the present invention. This second embodiment is substantially similar to the aforesaid first embodiment with the exception of the structure of the carrier.

The carrier 70 has a concavity 72 in communication with the curved channel 82 of the spacer 80 to increase the capacity of the curved channel 82 for passage of the external signal, thereby achieving the same purpose as the aforesaid first embodiment.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A MEMS module package comprising:
a carrier;
a lid capped on the carrier and having a chamber and a receiving hole in communication with the outsides;
a spacer disposed between the carrier and the lid and having a channel in communication between the chamber and the receiving hole of the lid; and
a chip received in the chamber of the lid and electrically connected with the carrier and mounted on the spacer in such a manner that the chip is corresponding to the curved channel.

2. The MEMS module package as claimed in claim 1, wherein the lid has a post extending from a top wall of the chamber and having the receiving hole.

3. The MEMS module package as claimed in claim 1, wherein the curved channel has a horizontal section and two vertical sections respectively communicating with the chamber and the receiving hole of the lid.

4. The MEMS module package as claimed in claim 1, wherein the carrier has a concavity in communication with the curved channel of the spacer.

5. The MEMS module package as claimed in claim 1, wherein the carrier is a ceramic substrate.

6. The MEMS module package as claimed in claim 1, wherein the carrier is a double-layer substrate.
